(19) United States
(12) Patent Application Publication
(10) Pub. No.: US 2024/0349502 A1
(43) Pub. Date: Oct. 17, 2024

(54) MEMORY DEVICE AND METHOD OF MANUFACTURING THE SAME

(71) Applicant: SK hynix Inc., Icheon-si Gyeonggi-do (KR)

(72) Inventors: Seok Min JEON, Icheon-si Gyeonggi-do (KR); Min Ho LEE, Icheon-si Gyeonggi-do (KR); Seong Man JEON, Icheon-si Gyeonggi-do (KR); Tae Hong GWON, Icheon-si Gyeonggi-do (KR); Sung Soon KIM, Icheon-si Gyeonggi-do (KR); Ji Seong KIM, Icheon-si Gyeonggi-do (KR); Ki Gab YEON, Icheon-si Gyeonggi-do (KR); Sang Seob LEE, Icheon-si Gyeonggi-do (KR)

(73) Assignee: SK hynix Inc., Icheon-si Gyeonggi-do (KR)

(21) Appl. No.: 18/470,729

(22) Filed: Sep. 20, 2023

(30) Foreign Application Priority Data
Apr. 13, 2023 (KR) 10-2023-0048638

(51) Int. Cl. H10B 43/27; H10B 43/10

(52) U.S. Cl. CPC H10B 43/27; H10B 43/10

(57) ABSTRACT

A memory device includes first and second material layers alternately stacked; a vertical hole passing through the first and second material layers; first insulating patterns protruding from a side surface of the first material layers exposed through the vertical hole; a blocking layer formed along a surface of the second material layers exposed between the first insulating patterns, the blocking layer comprising a plurality of concave portions, each of which is between the first insulating patterns; and charge trap patterns formed in the concave portions, wherein portions of the blocking layer exposed between the charge trap patterns, wherein a tunnel insulating layer, a channel layer, and a core pillar, are formed in an area that is substantially surrounded by the charge trap patterns.

### CROSS-REFERENCE TO RELATED APPLICATION

The present application claims priority under 35 U.S.C. § 119 (a) to Korean patent application number 10-2023-0048638 filed on Apr. 13, 2023, in the Korean Intellectual Property Office, the entire disclosure of which is incorporated by reference herein.

### BACKGROUND

### 1. Technical Field

The present disclosure relates to a three-dimensional memory device and a method of manufacturing the same.

### 2. Related Art

A memory device may be classified as a volatile memory device and a non-volatile memory device. The non-volatile memory device retains stored data after power to the device is cut off, the volatile memory device on the other hand, does not retain stored when power is cut off.

The non-volatile memory device may include a NAND flash memory, a NOR flash memory, a resistive random access memory (ReRAM), a phase-change random access memory (PRAM), a magnetoresistive random access memory (MRAM), a ferroelectric random access memory (FRAM), a spin transfer torque random access memory (STT-RAM), and the like.

Non-volatile memory device requires good retention characteristics in order to maintain stored data. Retention characteristics of three-dimensional memory device having charge trap layers in which data is stored may deteriorate.

### SUMMARY

An embodiment of the present disclosure provides a non-volatile memory device and a method of manufacturing the same, which is capable of improving data retention of the non-volatile memory device.

According to an embodiment of the present disclosure, a memory device includes first and second material layers alternately stacked; a vertical hole passing through the first and second material layers; first insulating patterns protruding from a side surface of the first material layers exposed through the vertical hole; a blocking layer formed along a surface of the second material layers exposed between the first insulating patterns, the blocking layer comprising a plurality of concave portions, each of which is between the first insulating patterns; and charge trap patterns formed in the concave portions, wherein portions of the blocking layer exposed between the charge trap patterns, wherein a tunnel insulating layer, a channel layer, and a core pillar, are formed in an area that is substantially surrounded by the charge trap patterns.

According to an embodiment of the present disclosure, a method of manufacturing a memory device includes forming a vertical hole through interleaved first and second material layers, the vertical hole being substantially orthogonal to the first and second material layers and having a center axis; forming insulating patterns on surfaces of the first material layers, the insulating patterns extending away from the exposed surfaces toward the center axis, the formed insulating patterns having interleaved concave and convex portions; forming a blocking layer over the insulating patterns and over the second material layers; and forming charge trap patterns in concave portions located between adjacent insulating patterns.

According to an embodiment of the present disclosure, a method of manufacturing a memory device includes forming a substantially vertical hole through first and second material layers; forming recesses between the second material layers by removing portions of the first material layers exposed by the formation of the vertical hole; forming first insulating patterns in the recesses and in second insulating patterns, which pass partially through the first insulating patterns and which extend into the vertical hole; forming a blocking layer over the first insulating patterns, the second insulating patterns, and the second material layers, the blocking layer comprising a plurality of concave-shaped portions; and forming charge trap patterns in concave-shaped portions of the blocking layer.

According to the present technology, an integration degree and reliability of a memory device may be improved.

### BRIEF DESCRIPTION OF THE DRAWINGS

FIG. 1 is a diagram illustrating a memory device according to an embodiment of the present disclosure.

FIG. 2 is a circuit diagram illustrating a memory block.

FIG. 3 is a diagram illustrating a structure of a memory device according to a first embodiment of the present disclosure.

FIGS. 4A to 4M are diagrams illustrating steps of a method of manufacturing the memory device according to the first embodiment of the present disclosure.

FIGS. 5A and 5B are diagrams illustrating a planar structure of the memory device according to the first embodiment of the present disclosure.

FIG. 6 is a diagram illustrating a structure of a memory device according to a second embodiment of the present disclosure.

FIGS. 7A to 7K are diagrams illustrating steps of a method of manufacturing the memory device according to the second embodiment of the present disclosure.

FIGS. 8A and 8B are diagrams illustrating a planar structure of the memory device according to the second embodiment of the present disclosure.

FIG. 9 is a diagram illustrating a solid state drive (SSD) system to which a memory device of the present disclosure is applied.

FIG. 10 is a diagram illustrating a memory card system to which a memory device of the present disclosure is applied.

### DETAILED DESCRIPTION

The embodiments disclosed herein should not be construed as limiting the scope of the appurtenant claims because the disclosed embodiments are merely exemplars of the claimed subject matter.

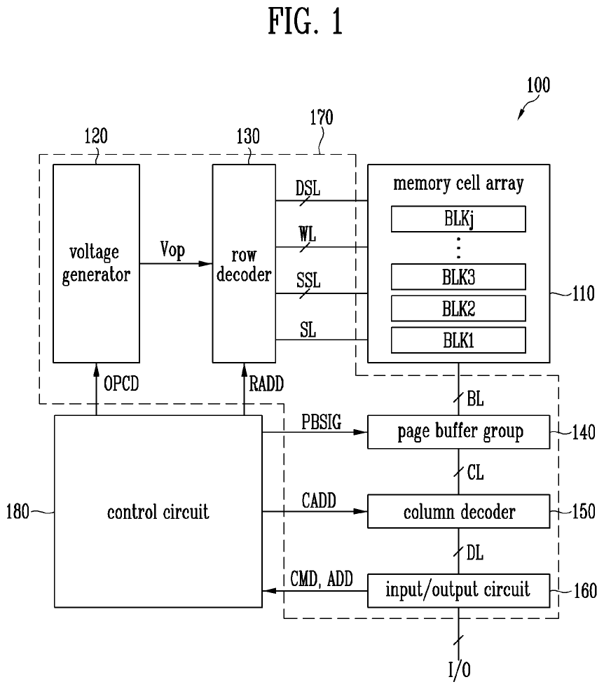

FIG. 1 is a diagram illustrating a memory device according to an embodiment of the present disclosure.

As FIG. 1 shows, the memory device 100 may include a memory cell array 110, a peripheral circuit 170, and a control circuit 180. As used herein, the word “data” should be broadly construed. “Data” as used herein may include program instructions, factual information such as measurements or statistics used as a basis for reasoning, discussion, or calculation digital data, information output by or received from a sensing device as well as information in any numerical form that can be digitally stored, transmitted or otherwise processed, et al. The memory cell array 110 may include first to j-th memory blocks BLK1 to BLKj. The first to j-th memory blocks BLK1 to BLKj may be formed in a three-dimensional structure. The first to j-th memory blocks BLK1 to BLKj formed in the three-dimensional structure may include memory cells stacked on a substrate in a vertical direction.

The memory cells may store data as 1 bit or 2 bits or more, according to a memory cell programming method. For example, a method in which 1 bit of data is stored in one memory cell is referred to as a single level cell method. A method in which 2 bits of data is stored in one memory cell is referred to as a two-level or multi-level cell method. A method in which 3 bits of data is stored in one memory cell is referred to as a triple level or tri-level cell method. A method in which 4 bits of data is stored in one memory cell is referred to as a quad level cell method. Using other methods, five or more bits of data may be stored in one memory cell.

The peripheral circuit 170 may be configured to perform a program operation of storing data in the memory cell array 110, a read operation of outputting the data stored in the memory cell array 110, and an erase operation of erasing the data stored in the memory cell array 110. For example, the peripheral circuit 170 may include a voltage generator 120, a row decoder 130, a page buffer group 140, a column decoder 150, and an input/output circuit 160.

The voltage generator 120 may generate various operation voltages Vop used for the program operation, the read operation, or the erase operation in response to an operation code OPCD. For example, the voltage generator 120 may be configured to generate program voltages, pass voltages, turn on voltages, turn off voltages, a ground voltage, negative voltages, source voltages, verify voltages, read voltages, erase voltages, precharge voltages, and the like, responsive to corresponding operation codes (op codes) received by the voltage generator 170.

The program voltages may be voltages applied to a selected word line among word lines WL during the program operation, and may be used to increase a threshold voltage of memory cells connected to the selected word line. The pass voltages may be voltages applied to unselected word lines among the word lines WL during the program or read operation, and may be used to turn on memory cells connected to the unselected word lines.

The turn on voltages may be voltages applied to drain select lines DSL or source select lines SSL, and may be used to turn on drain select transistors or source select transistors. The turn off voltages may be voltages applied to the drain select lines DSL or the source select lines SSL, and may be used to turn off the drain select transistors or the source select transistors.

The ground voltage may be 0V (zero volts) voltage, and the negative voltages may be voltages lower than 0V. The source voltages may be voltages applied to a source line SL, and may be a negative voltage, a ground voltage, or a positive voltage. The verify voltages may be voltages for determining a threshold voltage of selected memory cells during the program or erase operation, and may be applied to all word lines connected to the selected word line or a selected memory block.

The read voltages may be voltages applied to the selected word line during the read operation, and may be used to determine data stored in the memory cells. The erase voltages may be voltages applied to the source line SL during the erase operation, and may be used to decrease the threshold voltage of the memory cells. The precharge voltage may be a positive voltage for precharging a channel of unselected strings during a verify operation or the read operation, and may be supplied to the source line SL.

The row decoder 130 may be connected to the voltage generator 120 through global lines. The row decoder 130 may also be connected to the first to j-th memory blocks BLK1 to BLKj through drain select lines DSL, word lines WL, source select lines SSL, and the source line SL. The row decoder 130 may be configured to transmit the operation voltages Vop to the drain select lines DSL, the word lines WL, the source select lines SSL, and the source line SL connected to a selected memory block according to a row address RADD.

The page buffer group 140 may include page buffers (not shown) commonly connected to the first to j-th memory blocks BLK1 to BLKj. For example, each of the page buffers (not shown) may be connected to the first to j-th memory blocks BLK1 to BLKj through bit lines BL. The page buffers (not shown) may sense a current or a voltage of the bit lines BL in response to page buffer control signals PBSIG.

The column decoder 150 may be configured to transmit data between the page buffer group 140 and the input/output circuit 160 in response to a column address CADD. For example, the column decoder 150 may be connected to the page buffer group 140 through column lines CL and may be connected to the input/output circuit 160 through data lines DL.

The input/output circuit 160 may be configured to receive or output a command CMD, an address ADD, or data through input/output lines I/O. For example, the input/output circuit 160 may transmit the command CMD and the address ADD received from an external controller to the control circuit 180 through the input/output lines I/O, and may transmit the data received from the external controller to the column decoder 150 through the input/output lines I/O. Alternatively, the input/output circuit 160 may output the data received from the column decoder 150 to the external controller through the input/output lines I/O.

The control circuit 180 may output the operation code OPCD, the row address RADD, the page buffer control signals PBSIG, and the column address CADD in response to the command CMD and the address ADD. For example, then the command CMD input to the control circuit 180 is a command corresponding to the program operation, the control circuit 180 may control the peripheral circuit 170 to perform the program operation of the memory block selected by the address ADD. When the command CMD input to the control circuit 180 is a command corresponding to the read operation, the control circuit 180 may control the peripheral circuit 170 to perform the read operation of the memory block selected by the address and output the read data. When the command CMD input to the control circuit 180 is a command corresponding to the erase operation, the control circuit 180 may control the peripheral circuit 170 to perform the erase operation of the selected memory block.

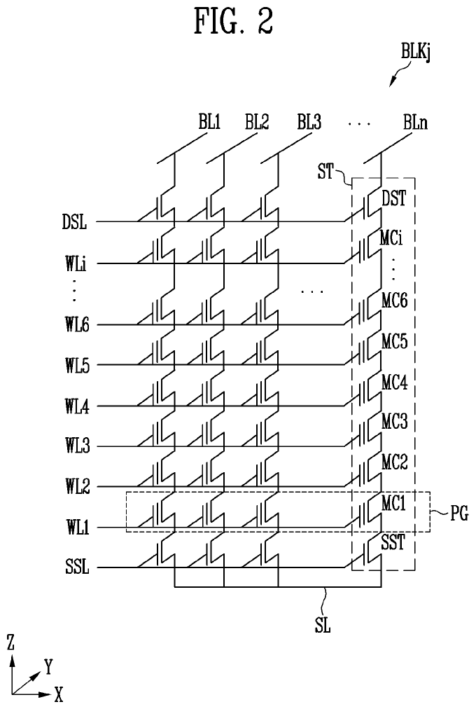

FIG. 2 is a circuit diagram illustrating a memory block.

Since the first to j-th memory blocks BLK1 to BLKj shown in FIG. 1 may be configured identically to each other, in FIG. 2, the j-th memory block BLKj among the first to j-th memory blocks BLK1 to BLKj is shown.

Referring to FIG. 2, the j-th memory block BLKj includes strings ST connected between first to n-th bit lines BL1 to BLn and the source line SL. Since the first to n-th bit lines BL1 to BLn extend along a Y direction and are arranged to be spaced apart from each other along an X direction, the strings ST extending in a Z direction may be arranged to be spaced apart from each other along the X and Y directions.

As shown in FIG. 2, each string ST may include a source select transistor SST, first to i-th, serially-connected memory cells MC1 to MCi, and a drain select transistor DST. Since the j-th memory block BLKj shown in FIG. 2 is a diagram for schematically describing a connection configuration of the memory block, the number of the source select transistors SST, the first to i-th memory cells MC1 to MCi, and the drain select transistors DST included in the strings ST may be changed according to the memory device.

The gate of each source select transistors SST for each string ST may be connected to the same source select line SSL. The gates of the first to i-th memory cells MC1 to MCi may be connected to first to i-th word lines WL1 to WLi. The gate of each drain select transistor DST of each string ST, may be connected to the same drain select line DSL.

Among the first to i-th memory cells MC1 to MCi, memory cells formed on the same horizontal layer may be connected to the same word line. For example, the first memory cells MC1 included in different strings ST may be commonly connected to the first word line WL1, and the i-th memory cells included in different strings ST may be common connected to the i-th word line WLi. A group of memory cells included in different strings ST and connected to the same word line becomes a page PG. The program and read operations may be performed in a unit of the page PG, and the erase operation may be performed in a unit of the memory block.

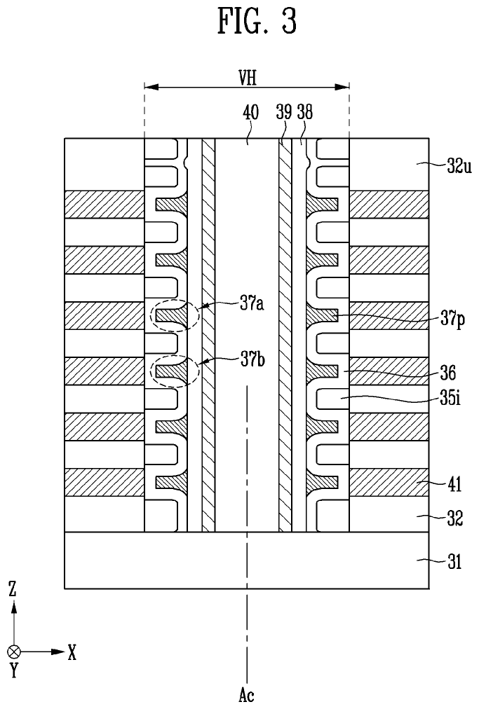

FIG. 3 is a diagram illustrating a structure of a memory device according to a first embodiment of the present disclosure.

Referring to FIG. 3, a memory block included in the memory device according to the first embodiment may include first and third material layers 32 and 41 stacked on a lower structure 31, a vertical hole VH, having a center or central axis Ac, is formed through and orthogonal to the first material layers 32 and the third material layers 41. Since the vertical hole VH extends through the first and third material layers 32 and 41, the shape of the vertical VH can also be considered to be a tube, which is a hollow elongated cylinder, the outer or peripheral surface of which are the materials that the vertical hole VH passes through, i.e., the stacked layers. As shown in FIG. 3, each layer of the several layers formed within the vertical hole VH, is located at a correspondingly different radial distance away from the center axis Ac of the vertical hole VH.

Insulating patterns 35i, a blocking layer 36, charge trap patterns 37p, a tunnel insulating layer 38, a channel layer 39, and a core pillar 40 are formed in the vertical hole VH.

The lower structure 31 may be a substrate or a source line. The first material layers 32 may be insulating layers. The third material layers 41 may be formed of a conductive layer that may be used as gate lines. For example, the third material layers 41 may be formed of at least one of tungsten (W), cobalt (Co), nickel (Ni), molybdenum (Mo), silicon (Si), and polysilicon (poly-Si), and may be formed of various other conductive layers. The insulating patterns 35i, the blocking layer 36, and the tunnel insulating layer 38 may be formed of an insulating layer such as an oxide layer. The charge trap patterns 37p may be formed of a nitride layer. The channel layer 39 may be formed of a conductive layer such as a doped silicon layer. The core pillar 40 may be formed of an insulating material or a conductive material.

Each of the insulating patterns 35i may be formed on a side surface of the first material layers 32 exposed through the vertical holes VH. For example, the insulating patterns 35i may protrude from the first material layers 32 such that the insulating patterns 35i extend inwardly toward a central axis, Ac, of the vertical hole VH.

The blocking layer 36 may be formed along a surface of the third material layers 41 and the insulating patterns 35i exposed through the vertical hole VH. Since the insulating patterns 35i protrude from a side surface of the vertical hole VH, the blocking layer 36 may be formed in a concave-convex structure.

The charge trap patterns 37p may be formed in a concave portion of the blocking layer 36 having the concave-convex structure. For example, the blocking layer 36 and the charge trap patterns 37p may be formed between the insulating patterns 35i adjacent to each other in a vertical direction, and the charge trap patterns 37p may be formed in the concave portion of the concave-convex structure formed by the blocking layer 36. That is, charge trap patterns 37a and 37b adjacent in the vertical direction are separated from each other by the insulating patterns 35i and the blocking layer 36. Since the charge trap patterns 37p formed in different layers are not connected to each other and are spaced apart from each other, a negative charge trapped in the charge trap patterns 37p by the program operation does not move to the charge trap patterns 37p adjacent in the vertical direction. Due to such a structure, a retention characteristic of the memory device may be improved, and thus reliability of the memory device may be improved.

Since a distance between the insulating patterns 35i formed on a side surface of the first material layer 32 positioned at the uppermost end 32u of the first material layers 32 is relatively narrower than another area, the charge trap patterns 37p may not be formed, at the uppermost end 32u. In such an embodiment, only the blocking layer 36 may be formed between insulating patterns 35i formed on the side surface of the first material layer 32 at the uppermost end 32u.

The tunnel insulating layer 38 may be formed in a cylindrical shape along a side surface of the blocking layer 36 and the charge trap patterns 37p exposed in the vertical hole VH. The channel layer 39 may be formed in a cylindrical shape along an inner side surface of the tunnel insulating layer 38. The core pillar 40 may be formed in a cylindrical shape in an area surrounded by the channel layer 39.

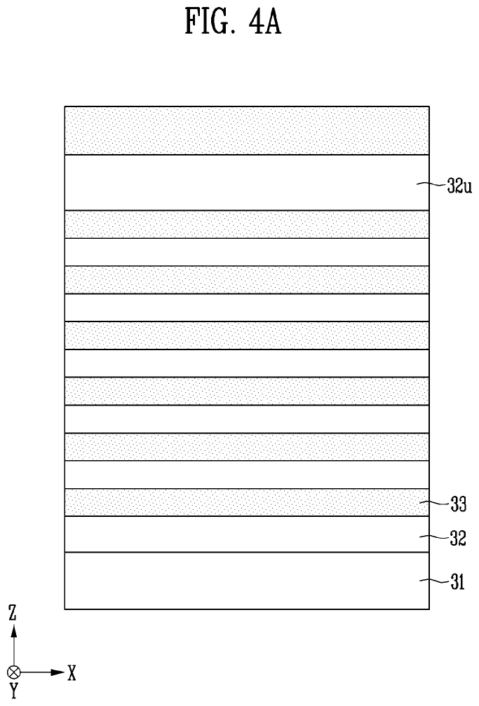

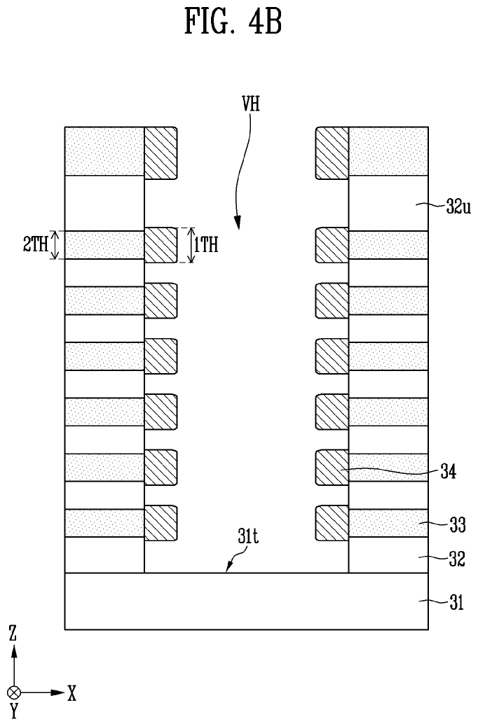

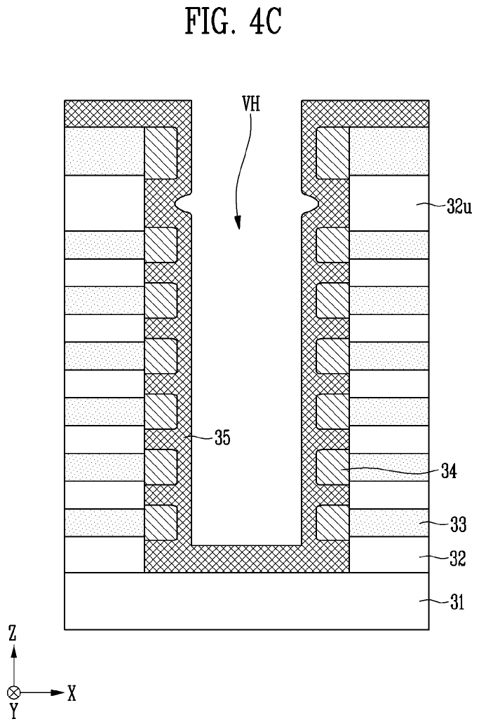

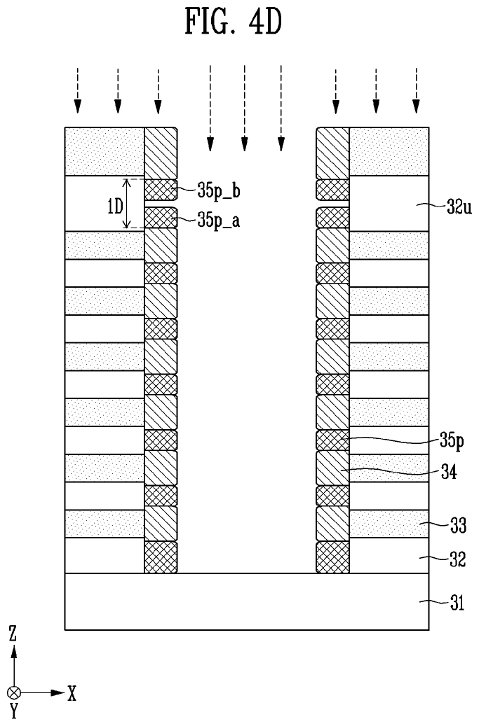

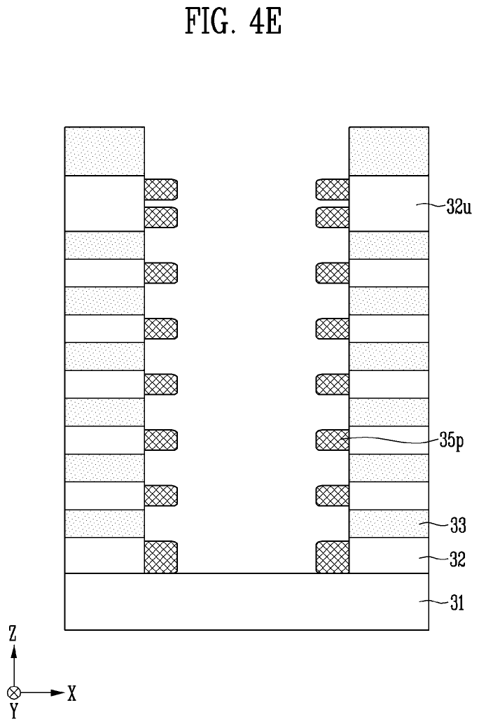

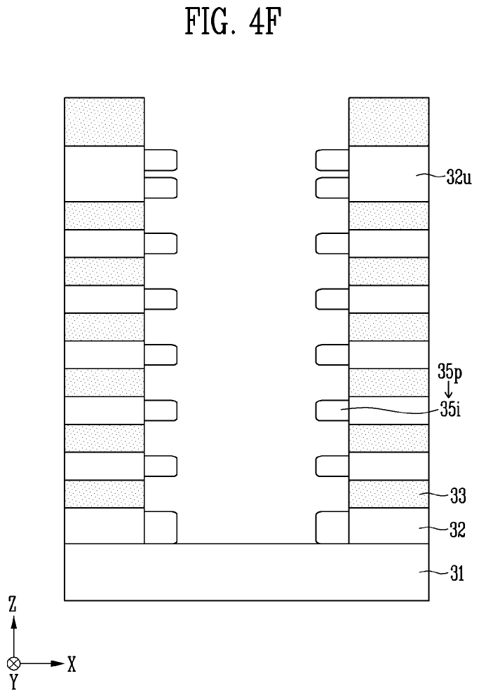

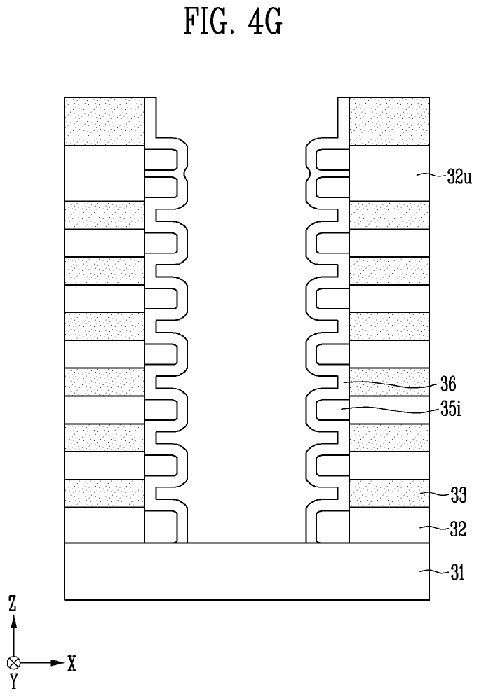

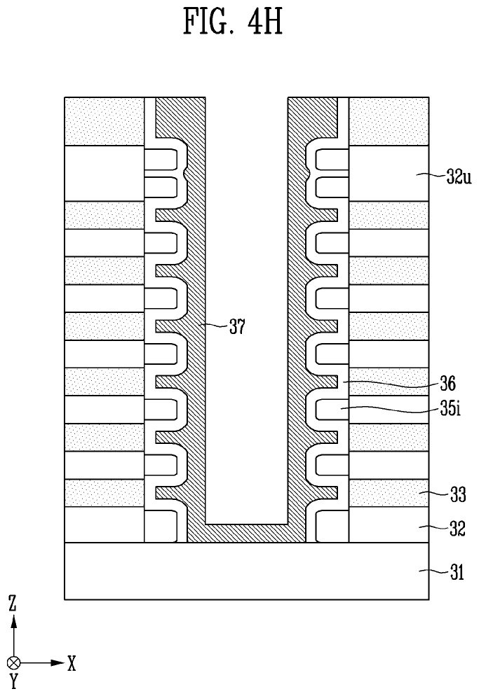

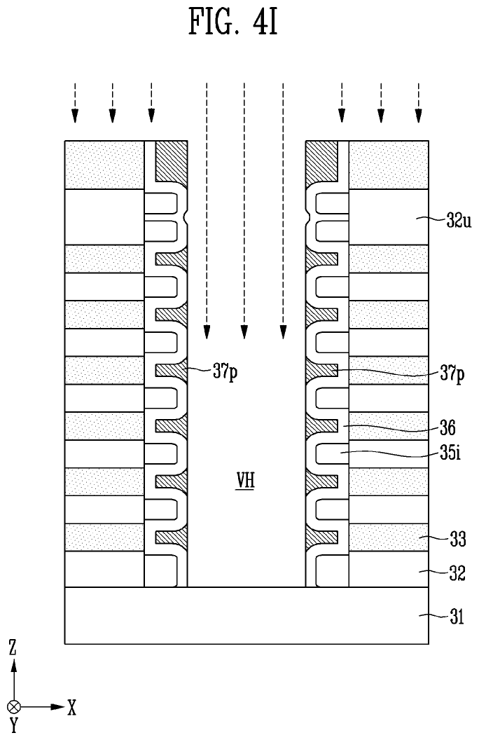

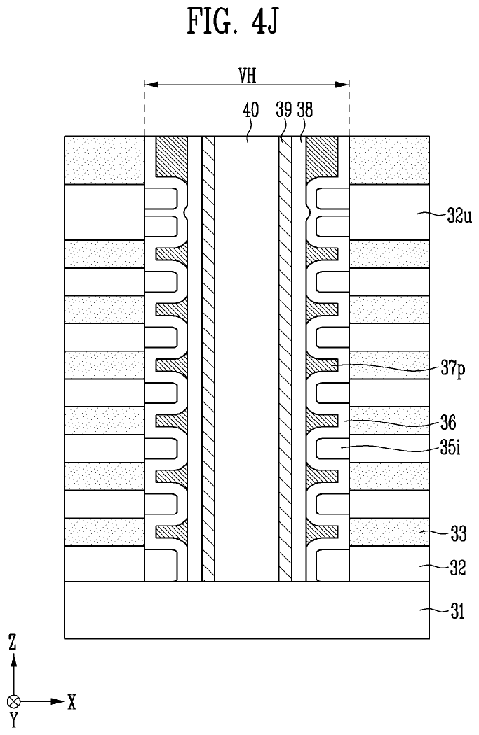

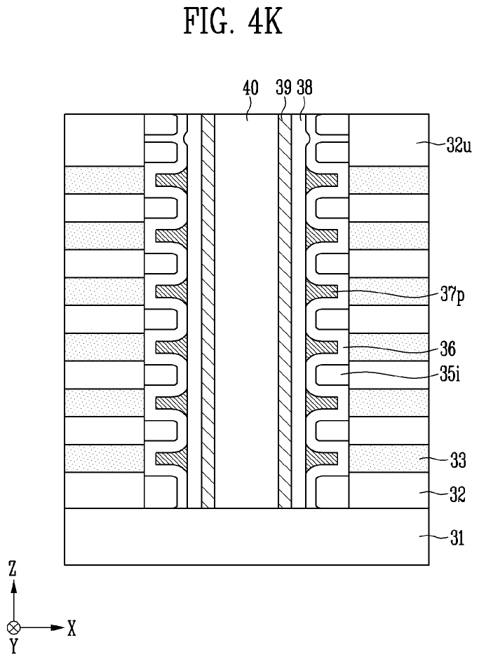

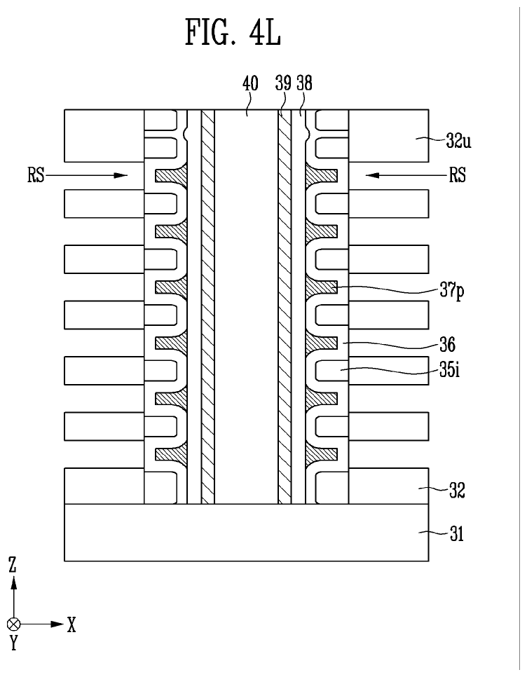

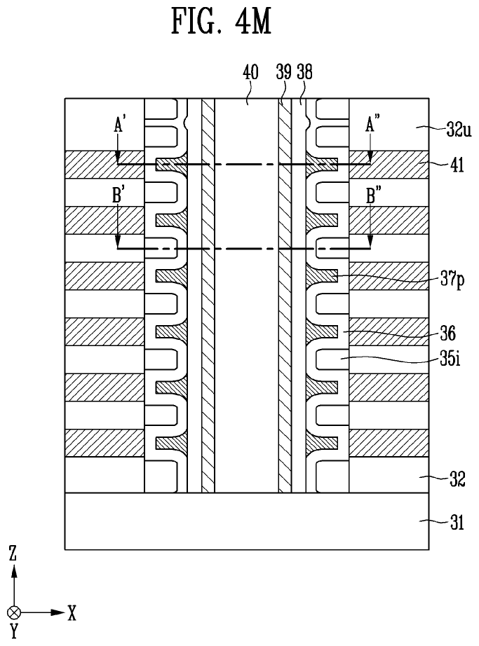

FIGS. 4A to 4M are diagrams illustrating steps of a method of manufacturing the memory device according to the first embodiment of the present disclosure.

Referring to FIG. 4A, first and second material layers 32 and 33 respectively, may be alternately stacked on the lower structure 31. As stated above, the lower structure 31 may be a substrate or a source line, and may also be a peripheral circuit structure formed on the substrate. The first material layers 32 may thus be formed of an insulating material layer such as an oxide layer or it may be a conductive material.

The second material layers 33 may be layers that are removed in a subsequent process, and may be formed of a material having an etch selectivity difference from the first material layers 32. For example, the second material layers 33 may be a nitride layer. The second material layer 33 may also be formed on the uppermost end 32u of the stacked first and second material layers 32 and 33. The first and second material layers 32 and 33 at the uppermost end 32u of the first and second material layers 32 and 33 may be formed relatively thicker than another area in consideration of a thickness of a capping layer (not shown) that may be formed to reduce a resistance of an area where a drain select transistor is to be formed.

Referring to FIG. 4B, the vertical hole VH passing through the first and second material layers 32 and 33 may be formed. For example, the vertical hole VH may be formed by etching a portion of the first and second material layers 32 and 33 until the top surface 31t of the lower structure 31 is exposed. Therefore, the lower structure 31 may be exposed through a lower surface of the vertical hole VH, and the first and second material layers 32 and 33 may be exposed through the side surface. First sacrificial layers 34 may be selectively formed on the side surfaces of the second material layers 33 of the first and second material layers 32 and 33 exposed through the vertical hole VH. For example, the first sacrificial layers 34 may be grown from the exposed surface of the second material layers 33 and be formed of an oxide or a material including an oxide. The first sacrificial layers 34 may have a thickness, 1TH, greater than the thickness 2TH of the second material layers 33. At this time, the thickness 1TH may be adjusted so that the first sacrificial layers 34 adjacent to each other in the vertical direction do not come into contact with each other. Therefore, the first material layers 32 may be exposed between the first sacrificial layers 34 adjacent to each other in the vertical direction.

Referring to FIG. 4C, second sacrificial layers 35 may be formed over the entire vertical surface of the vertical hole VH to fill all areas between the first sacrificial layers 34. For example, the second sacrificial layers 35 may be formed so that all of the uppermost end 32u of the stacked first and second material layers 32 and 33, the first sacrificial layers 34 and the first material layers 32 formed on the side surface of the vertical hole VH, and a lower surface of the vertical hole VH are covered. The second sacrificial layers 35 may be formed of silicon or a material including silicon.

Referring to FIG. 4D, an etching process for removing the second sacrificial layers 35 formed at the upper end 32u of the first and second material layers 32 and 33, the second sacrificial layers 35 formed at a lower end of the vertical hole VH, and the second sacrificial layers 35 formed on a side surface of the first sacrificial layers 34 may be performed. The etching process may be performed as a dry etching process. For example, the etching process may be performed as an anisotropic dry etching process so that the second sacrificial layers 35 remain between the first sacrificial layers 34 adjacent in the vertical direction. In the anisotropic dry etching process, a source gas of which an etching selectivity of the second sacrificial layers 35 is higher than that of the first sacrificial layers 34 may be used.

After etching, the second sacrificial layers 35 remaining between the first sacrificial layers 34 become the second sacrificial patterns 35p. Second sacrificial patterns 35p_a and 35p_b remaining on a side surface of the first material layer 32 formed at the uppermost end 32u of the first material layers 32 may be spaced apart from each other, but may extend toward each other or thicken, until they occupy a distance 1D between the first sacrificial layers 34 at the uppermost end 32u. In the drawing, a structure in which the second sacrificial patterns 35p_a and 35p_b are spaced apart from each other is shown as an example.

Referring to FIG. 4E, an etching process for removing the first sacrificial layers 34 of FIG. 4D may be performed. The etching process may be performed in a dry or wet method. The dry etching process may be performed as an isotropic etching process. In the etching process of the dry method, a source gas of which an etching selectivity of the first sacrificial layers 34 of FIG. 4D is higher than that of the second sacrificial patterns 35p may be used. In the etching process of the wet method, an etchant of which an etching selectivity of the first sacrificial layers 34 of FIG. 4D is higher than that of the second sacrificial patterns 35p may be used.

Referring to FIG. 4F, an oxidation process for oxidizing the second sacrificial patterns 35p may be performed. For example, since the second sacrificial patterns 35p are formed of silicon or a material including silicon, the second sacrificial patterns 35p may be oxidized by the oxidation process and changed to the insulating patterns 35i. Therefore, the insulating patterns 35i may be a silicon oxide layer.

Referring to FIG. 4G, the blocking layer 36 may be formed along a surface of the insulating patterns 35i and the second material layers 33 formed on the side surface of the vertical hole VH. The blocking layer 36 may be formed of an insulating layer, for example, an oxide layer. Since the insulating patterns 35i protrude from the first material layers 32, the blocking layer 36 may be formed in a concave-convex shape along the surface of the insulating patterns 35i and the second material layers 33. That is, the blocking layer 36 may be formed in a concave shape between the insulating patterns 35i adjacent in the vertical direction.

Referring to FIG. 4H, the charge trap layer 37 may be formed along a surface of the blocking layer 36 to fill the concave portion of the blocking layer 36. The charge trap layer 37 may be formed of a nitride layer. For example, the charge trap layer 37 may be formed to cover the entire surface of the blocking layer 36 so that the concave portion of the blocking layer 36 is sufficiently filled with the charge trap layer 37.

Referring to FIG. 4I, an etching process for removing the charge trap layer 37 formed at a lower end of the vertical hole VH and the charge trap layer 37 formed on the side surface of the blocking layer 36 may be performed. The etching process may be performed as a dry etching process. For example, the etching process may be performed by an anisotropic dry etching process so that the charge trap layer 37 remains in the concave portion of the blocking layer 36. In the anisotropic dry etching process, a source gas of which an etching selectivity of the charge trap layer 37 is higher than that of the blocking layer 36 may be used. The charge trap layer 37 remaining in the concave portion of the blocking layer 36 becomes the charge trap patterns 37p. The charge trap patterns 37p are radially aligned with the second material layers 33. Therefore, since the insulating patterns 35i and the blocking layer 36 are positioned between the charge trap patterns 37p adjacent in the vertical direction, the charge trap patterns 37p adjacent in the vertical direction are separated from each other by insulating materials.

Referring to FIG. 4J, the tunnel insulating layer 38, the channel layer 39, and the core pillar 40 may be sequentially formed along an inner side surface of the vertical hole VH in which the charge trap patterns 37p are formed. The tunnel insulating layer 36 may be formed of an oxide layer. The channel layer 39 may be formed of a doped silicon layer. The core pillar 40 may be formed of an insulating layer or a conductive layer. The tunnel insulating layer 38 may be formed in a cylindrical shape along a surface of the charge trap patterns 37p and the blocking layer 36. The channel layer 39 may be formed in a cylindrical shape along the inner side surface of the tunnel insulating layer 38. The core pillar 40 may be formed in a cylindrical shape in an area surrounded by the channel layer 39.

Referring to FIG. 4K, a planarization process may be performed to expose the first material layer 32 that is formed on the uppermost end 32u of the first material layers 32. The planarization process may be a chemical mechanical polishing (CMP) process. As an upper surface of the planarized entire structure, a portion of the first material layers 32, the insulating patterns 35i, the blocking layer 36, the tunnel insulating layer 38, the channel layer 39, and the core pillar 40 may be exposed.

Referring to FIG. 4L, an etching process for removing the second material layers 33 may be performed. Since the second material layers 33 are formed between the first material layers 32, the etching process may be performed as an isotropic dry etching process or a wet etching process. The second material layers 33 may be removed, and thus recesses RS may be formed between the first material layers 32. Therefore, the first material layers 32 and the blocking layer 36 may be exposed through the recesses RS. Although not shown in the drawing, the second material layers 33 may be removed through a slit separating between memory blocks.

Referring to FIG. 4M, the third material layers 41 may be formed between the first material layers 32. Since the third material layers 41 are used as gate lines, the third material layers 41 may be formed as conductive layers. For example, the third material layers 41 may be formed of at least one of tungsten (W), cobalt (Co), nickel (Ni), molybdenum (Mo), silicon (Si), and polysilicon (poly-Si), and may be formed of various other conductive layers.

A planar structure of the memory block manufactured according to the above-described manufacturing method is described as follows with reference to a plane taken in a A′-A″ direction and a plane taken in a B′-B″ direction.

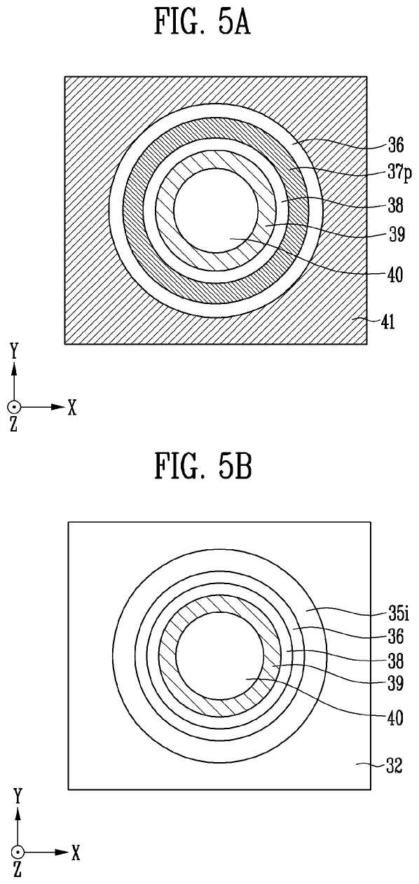

FIGS. 5A and 5B are diagrams illustrating the planar structure of the memory device according to the first embodiment of the present disclosure.

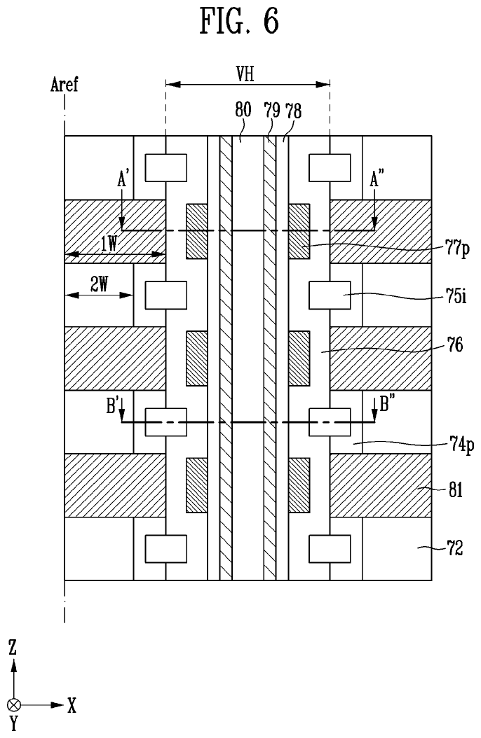

FIG. 5A shows a plan view of the memory block across section lines A′-A″ that are depicted in FIG. 6.

FIG. 5B shows a plan view across section lines B′-B″ that are depicted in FIG. 6.

Referring to FIGS. 4M and 5A, the blocking layer 36 is cylindrically shaped. The periphery of the blocking layer 36 is surrounded by the third material layer 41. The charge trap pattern 37p may have a cylindrical shape and be formed over the inner surface of the blocking layer 36. The tunnel insulating layer 38 may be formed in a cylindrical shape along an inner surface of the charge trap pattern 37p. The channel layer 39 may be formed in a cylindrical shape along an inner surface of the tunnel insulating layer 38. The core pillar 40 may be formed in a cylindrical shape along an inner surface of the channel layer 39.

Referring to FIGS. 4M and 5B, an insulating pattern 35i is formed in a cylindrical shape, and a periphery of the insulating pattern 35i is surrounded by the first material layer 32. The blocking layer 36 may be formed in a cylindrical shape along an inner surface of the insulating pattern 35i. The tunnel insulating layer 38 may be formed in a cylindrical shape along the inner surface of the blocking layer 36. The channel layer 39 may be formed in a cylindrical shape along the inner surface of the tunnel insulating layer 38. The core pillar 40 may be formed in a cylindrical shape along the inner surface of the channel layer 39.

FIG. 6 is a diagram illustrating a structure of a memory device according to a second embodiment of the present disclosure.

Referring to FIG. 6, a memory block according to the second embodiment may include first and third material layers 72 and 81 respectively, stacked on a lower structure (not shown), first insulating patterns 74p, a vertical hole VH passing orthogonally through the first and third material layers 72 and 81, respectively, second insulating patterns 75i formed in the vertical holes VH, a blocking layer 76, charge trap patterns 77p, a tunnel insulating layer 78, a channel layer 79, and a core pillar 80.

The first material layers 72 may be insulating layers. The third material layers 81 may be formed of conductive layers that may be used as gate lines and may be made of tungsten (W), cobalt (Co), nickel (Ni), molybdenum (Mo), silicon (Si), and polysilicon (poly-Si), and may be formed of various other conductive layers. The first insulating patterns 74p, the second insulating patterns 75i, the blocking layer 76, and the tunnel insulating layer 78 may be formed of an insulating layer such as an oxide layer. The charge trap patterns 77p may be formed of a nitride layer. The channel layer 79 may be formed of a conductive layer such as a doped silicon layer. The core pillar 80 may be formed of an insulating material or a conductive material.

The first and third material layers 72 and 81 respectively, may have different widths from a reference axis Aref. Assuming that the reference axis Aref is positioned outside the vertical hole VH, the third material layers 81 may have a first distance or width 1W from the reference axis Aref, and the first material layers 72 may have a second distance or width 2W narrower than the first width 1W. Therefore, a distance between the third material layers 81 from the central axis of the vertical hole VH is shorter than a distance between the first material layers 72 from the central axis of the vertical hole VH. The first insulating patterns 74p may be formed in an area where a distance difference or a width difference occurs between the first and third material layers 72 and 81 respectively. For example, a sum of the width of the first material layer 72 and a width of the first insulating pattern 74p formed on the same layer may be equal to the first width 1W of the third material layer 81. The first and second insulating patterns 74p and 75i are formed between the third material layers 81 and are spaced apart from each other in an area where the third material layers 81 are formed.

The second insulating patterns 75i may be formed between the first insulating patterns 74p and the blocking layer 76. For example, the first insulating patterns 74p may be formed in a concave shape in a direction away from the vertical hole VH, and the second insulating patterns 75i may be formed in a portion where the first insulating patterns 74p are concave. The blocking layer 76 may extend in the vertical direction, may be formed in a concave shape. i.e., hollowed or rounded inwardly like the inside of a bowl, along the length of the vertical hole VH where the first material layers 72 are formed, and may be formed in a concave shape in a direction away from the vertical hole VH in a layer where the third material layers 81 are formed.

In the layer where the third material layers 81 are formed, the charge trap patterns 77p may be formed in a portion where the blocking layer 76 is concave. The charge trap patterns 77p are spaced apart from each other in the vertical direction. For example, the charge trap patterns 77p adjacent in the vertical direction are separated from each other by the second insulating patterns 75i and the blocking layer 76. Since the charge trap patterns 77p formed in different layers are not connected to each other but are spaced apart from each other, a negative charge trapped in the charge trap patterns 77p does not move to the charge trap patterns 77p adjacent in the vertical direction by the program operation. Due to such a structure, a retention characteristic of the memory device may be improved, and thus reliability of the memory device may be improved.

The tunnel insulating layer 78 may be formed in a cylindrical shape along a side surface of the blocking layer 76 and the charge trap patterns 77p. The channel layer 79 may be formed in a cylindrical shape along an inner side surface of the tunnel insulating layer 78. The core pillar 80 may be formed in a cylindrical shape in an area surrounded by the channel layer 79.

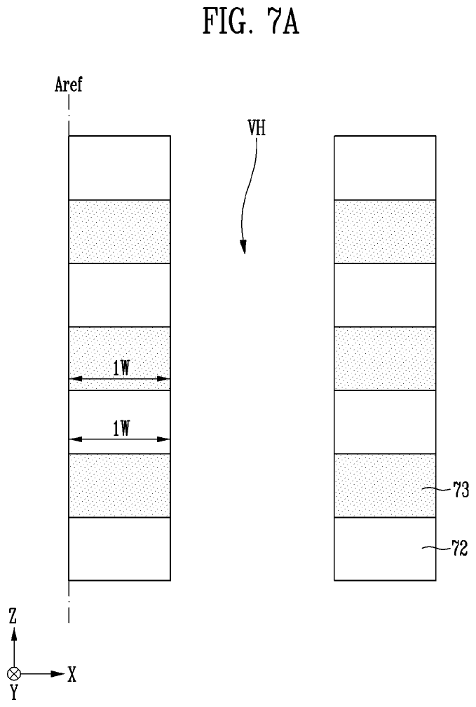

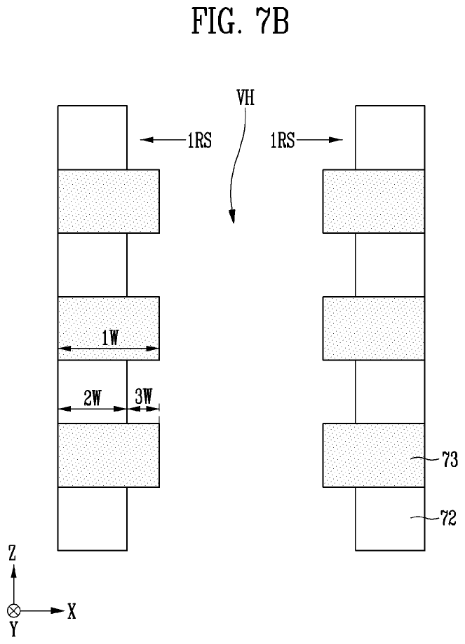

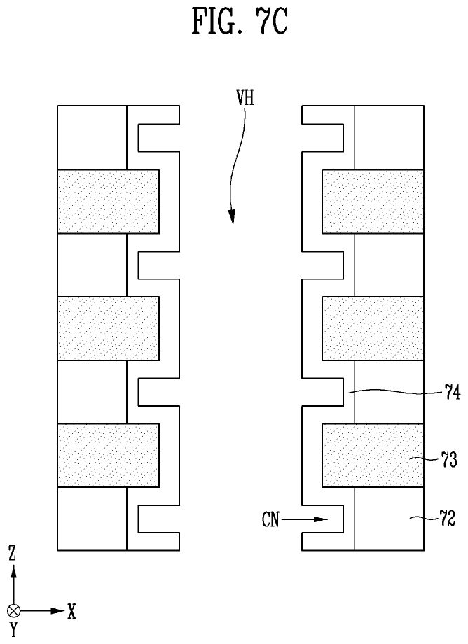

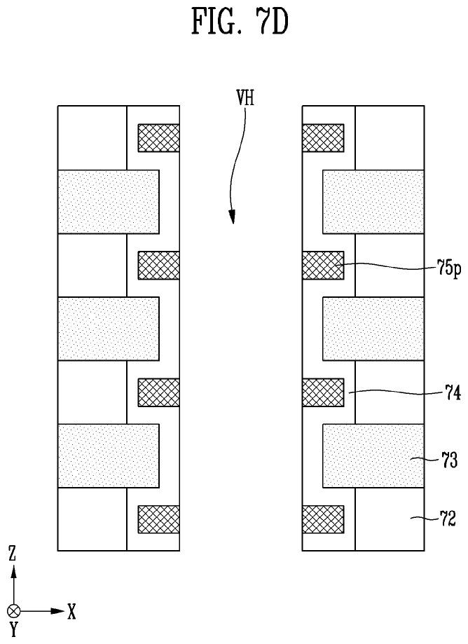

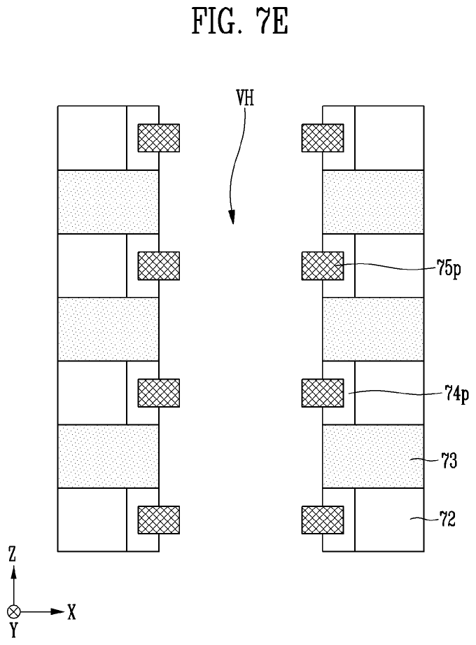

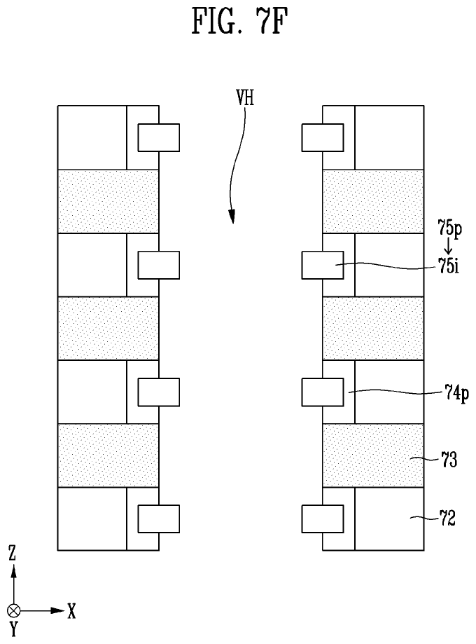

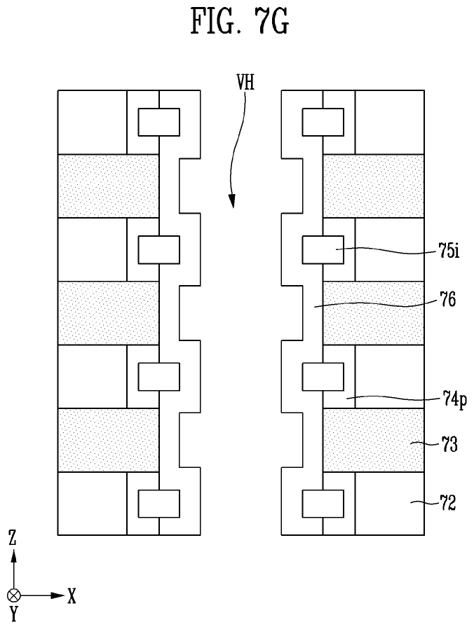

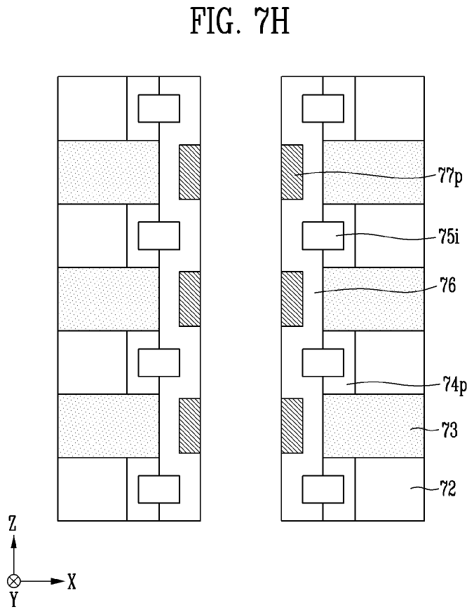

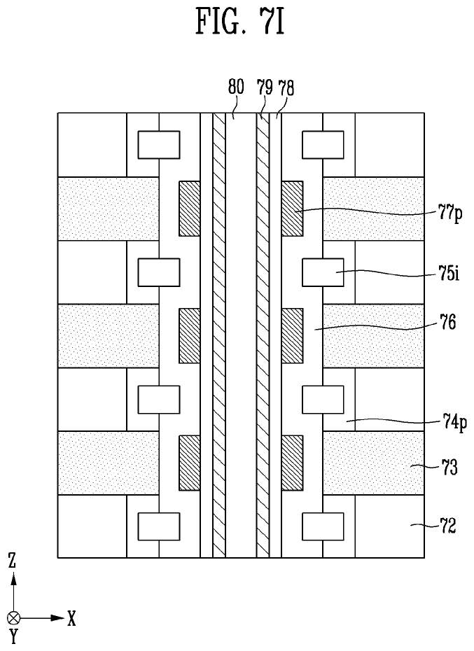

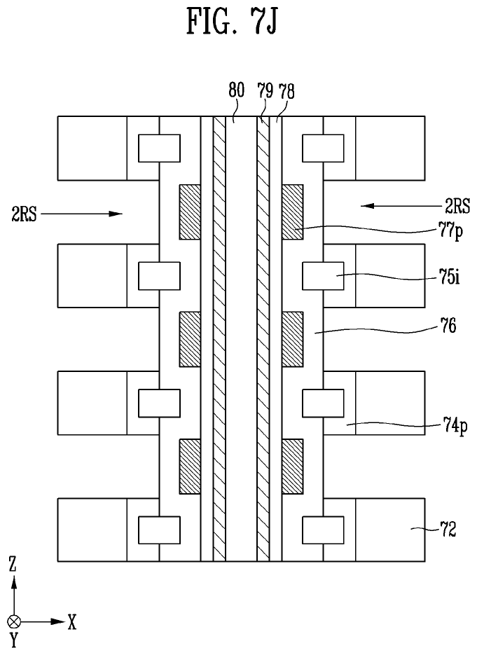

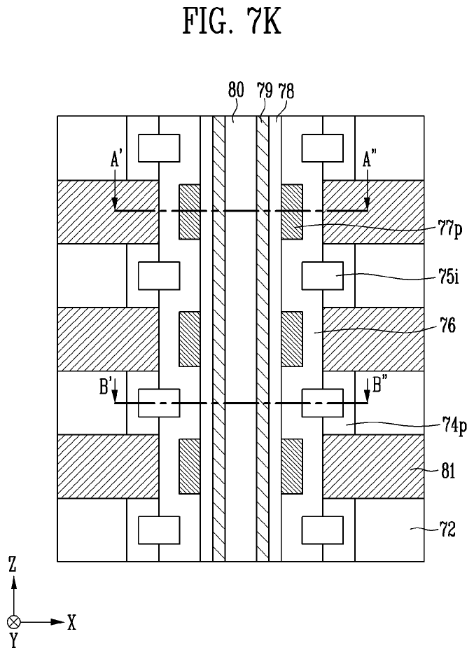

FIGS. 7A to 7K are diagrams illustrating a method of manufacturing the memory device according to the second embodiment of the present disclosure.

Referring to FIG. 7A, the first and second material layers 72 and 73 may be alternately stacked on the lower structure (not shown). The lower structure (not shown) may be a substrate or a source line, and may also be a peripheral circuit structure formed on the substrate. The first material layers 72 may be formed of an insulating layer such as an oxide layer. The second material layers 73 may be layers to be removed in a subsequent process, and may be formed of a material having an etch selectivity difference from that of the first material layers 72. For example, the second material layers 73 may be formed of a nitride layer.

When the first and second material layers 72 and 73 are stacked by a set number, a vertical hole VH passing through the first and second material layers 72 and 73 may be formed. A vertical hole VH may be formed by etching through all of the stacked first and second material layers 72 and 73 until the lower structure (not shown) is exposed. Side surfaces of the etched-through first and second material layers 72 and 73, i.e., the ring-shaped portions of the layers 72 and 73, may thus be exposed by the formation of the vertical hole VH. If a reference axis Aref is positioned in an outer direction from the vertical hole VH, the width of the first material layers 72 from the reference axis Aref may have the first width 1W, and the width of the second material layers 73 from the reference axis Aref may also have the first width 1W.

Referring to FIG. 7B, first recesses 1RS may be formed by removing a portion of the first material layers 72 exposed through the vertical hole VH. Each of the first material layers 72 may have a second width 2W, which is narrower than the first width 1W, by the depth of the first recesses 1RS. Assuming that a width of each of the first recesses 1RS is a third width 3W, a sum of the second and third widths 2W and 3W may be the first width 1W.

Referring to FIG. 7C, the insulating layer 74 may be formed along a surface of the first and second material layers 72 and 73 exposed through the vertical hole VH. For example, the insulating layer 74 may be formed of an oxide layer. Since a surface of the first and second material layers 72 and 73 exposed through the vertical hole VH have a concave-convex structure, the insulating layer 74 may also be formed with a concave-convex structure. For example, in the layer where the first material layers 72 are formed, the insulating layer 74 has a concave portion CN in a direction of the first material layers 72.

Referring to FIG. 7D, sacrificial patterns 75p may be formed in the concave portions CN of FIG. 7C of the insulating layer 74. The sacrificial patterns 75p may be formed in a method similar to the method in which the second sacrificial layers 35 of the first embodiment are formed. The sacrificial patterns 75p may be silicon or a material including silicon.

Referring to FIG. 7E, an etching process for removing a portion of the insulating layer 74 exposed between the sacrificial patterns 75p in the vertical hole VH may be performed. The insulating layer 74 may be etched until the second material layers 73 are exposed. Therefore, the insulating layer 74 remaining between the second material layers 73 is changed to the first insulating patterns 74p. That is, the first material layers 72, the first insulating patterns 74p, and the sacrificial patterns 75p are formed between the second material layers 73.

Referring to FIG. 7F, an oxidation process for oxidizing the sacrificial patterns 75p may be performed. For example, since the sacrificial patterns 75p are formed of the silicon or the material including silicon, the sacrificial patterns 75p may be oxidized by the oxidation process and changed to the second insulating patterns 75i.

Referring to FIG. 7G, the blocking layer 76 may be formed along a surface of the second material layers 73, the first insulating patterns 74p, and the second insulating patterns 75i exposed through the side surface of the vertical holes VH. The blocking layer 76 may be formed of an insulating layer such as an oxide layer. Since the second insulating patterns 75i protrude in the direction of the central axis of the vertical hole VH more than the second material layers 73 and the first insulating patterns 74p, the blocking layer 76 may be formed in a concave-convex shape. For example, the blocking layer 76 may be formed in a concave shape between the second insulating patterns 75i adjacent in the vertical direction.

Referring to FIG. 7H, the charge trap patterns 77p may be formed in a concave portion of the blocking layer 76. The charge trap patterns 77p may be formed in a method similar to the method of forming the charge trap patterns 37p of the first embodiment. The charge trap patterns 77p may be formed of a nitride layer. The charge trap patterns 77p may be formed in the concave portion of the blocking layer 76 and are not formed in a protruding portion of the blocking layer 76. Therefore, the charge trap patterns 77p are spaced apart from each other in the vertical direction.

Referring to FIG. 7I, the tunnel insulating layer 78, the channel layer 79, and the core pillar 80 may be sequentially formed along an inner surface of the vertical hole VH where the charge trap patterns 77p are formed. The tunnel insulating layer 76 may be formed of an oxide layer. The channel layer 79 may be formed of a doped silicon layer. The core pillar 80 may be formed of an insulating layer or a conductive layer. The tunnel insulating layer 78 may be formed in a cylindrical shape along a surface of the charge trap patterns 77p and the blocking layer 76. The channel layer 79 may be formed in a cylindrical shape along the inner side surface of the tunnel insulating layer 78. The core pillar 80 may be formed in a cylindrical shape in the area surrounded by the channel layer 79.

Referring to FIG. 7J, an etching process for removing the second material layers 73 may be performed. Since the second material layers 73 are formed between the first material layers 72, the etching process may be performed as an isotropic dry etching process or a wet etching process. The second material layers 73 may be removed, and thus second recesses 2RS may be formed between the first material layers 72. Therefore, a portion of the first material layers 72, the first insulating patterns 74p, and the blocking layer 76 may be exposed through the second recesses 2RS. Although not shown in the drawing, the second material layers 73 may be removed through a slit separating between memory blocks.

Referring to FIG. 7K, the third material layers 81 may be formed between the first material layers 72. Since the third material layers 81 are used as gate lines, the third material layers 81 may be formed of a conductive layer. For example, the third material layers 81 may be formed of at least one of tungsten (W), cobalt (Co), nickel (Ni), molybdenum (Mo), silicon (Si), and polysilicon (poly-Si), and may be formed of various other conductive layers.

A planar structure of the memory block manufactured according to the above-described manufacturing method is described with reference to a plane taken in the A′-A″ direction and a plane taken along in the B′-B″ direction.

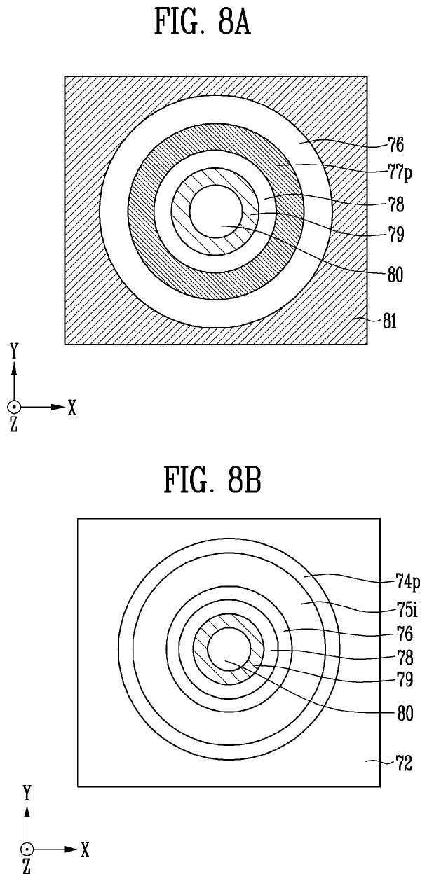

FIGS. 8A and 8B are diagrams illustrating a planar structure of the memory device according to the second embodiment of the present disclosure.

FIG. 8A shows a plan view of the A-A″ direction, and FIG. 8B shows a plan view of the B′-B″ direction.

Referring to FIGS. 7K and 8A, the blocking layer 76 is formed in a cylindrical shape, and a periphery of the blocking layer 76 is surrounded by the third material layer 81. The charge trap pattern 77p may be formed in a cylindrical shape along an inner surface of the blocking layer 76. The tunnel insulating layer 78 may be formed in a cylindrical shape along an inner surface of the charge trap pattern 77p. The channel layer 79 may be formed in a cylindrical shape along an inner surface of the tunnel insulating layer 78. The core pillar 80 may be formed in a cylindrical shape along an inner surface of the channel layer 79.

Referring to FIGS. 7K and 8B, the first insulating pattern 74p is formed in a cylindrical shape, and a periphery of the first insulating pattern 74p is surrounded by the first material layer 72. The second insulating pattern 75i may be formed in a cylindrical shape along an inner surface of the first insulating pattern 74p. The blocking layer 76 may be formed in a cylindrical shape along an inner surface of the second insulating pattern 75i. The tunnel insulating layer 78 may be formed in a cylindrical shape along the inner surface of the blocking layer 76. The channel layer 79 may be formed in a cylindrical shape along the inner surface of the tunnel insulating layer 78. The core pillar 80 may be formed in a cylindrical shape along the inner surface of the channel layer 79.

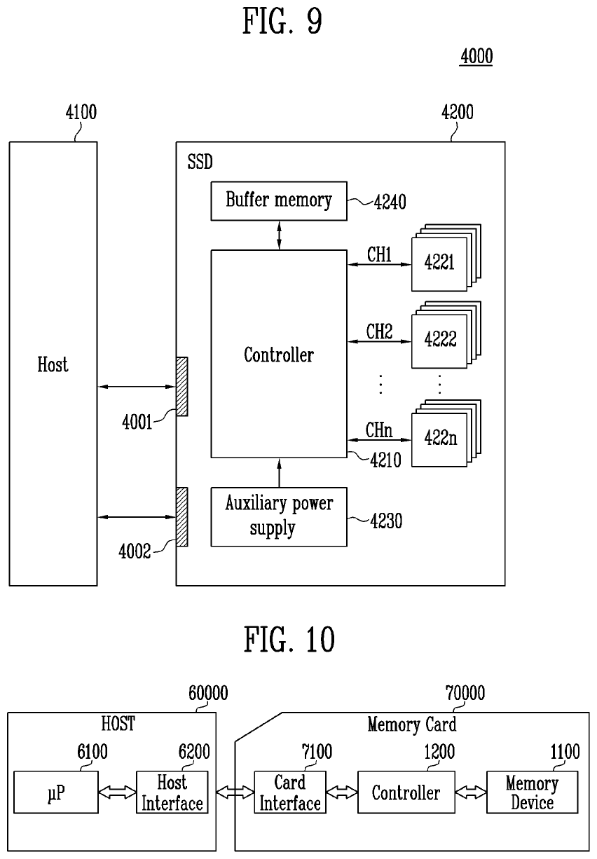

FIG. 9 is a diagram illustrating a solid state drive (SSD) system to which a memory device of the present disclosure is applied.

Referring to FIG. 9, the SSD system 4000 includes a host 4100 and an SSD 4200. The SSD 4200 includes a controller 4210, memory devices 4221 to 422n, an auxiliary power supply 4230, and a buffer memory 4240. The SSD 4200 may exchange signals with the host 4100 through a signal connector 4001. It may receive power through a power connector 4002.

According to an embodiment of the present disclosure, each memory device 4221 to 422n may be configured identically to the memory device 100 described above and depicted in FIG. 1.

The controller 4210 may control the plurality of memory devices 4221 to 422n in response to signals received from the host 4100. The signals may be defined by an a particular interface, such as a universal serial bus (USB), a multimedia card (MMC), an embedded MMC (eMMC), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The auxiliary power supply 4230 may be connected to the host 4100 through the power connector 4002. The auxiliary power supply 4230 may receive power from the host 4100 and may change the voltage of the provided power. The auxiliary power supply 4230 may provide power to the SSD 4200 when power supply from the host 4100 is lost or if the voltage is sufficiently steady, i.e., not sufficiently smooth. The auxiliary power supply 4230 may be located inside or outside the SSD 4200.

The buffer memory 4240 may be a buffer memory for the SSD 4200, temporarily storing data received from the host 4100 or data from the memory devices 4221 to 422n, that is to be sent to the host. The buffer memory 4240 may also temporarily store metadata (for example, a mapping table of the memory devices 4221 to 422n).

The buffer memory 4240 may be embodied as a volatile memory such as a DRAM, an SDRAM, a DDR SDRAM, and an LPDDR SDRAM as well as a nonvolatile memory such as an FRAM, a ReRAM, an STT-MRAM, and a PRAM.

FIG. 10 is a diagram illustrating a memory card system to which a memory device of the present disclosure is applied. Referring to FIG. 10, the memory system 70000 may be implemented as a memory card or a smart card. The memory system 70000 may include a memory device 1100, a controller 1200, and a card interface 7100. The memory device 1100 may be configured identically to the memory device 100 shown in FIG. 1. The controller 1200 may control data exchange between the memory device 1100 and the card interface 7100. According to an embodiment, the card interface 7100 may be a secure digital (SD) card interface or a multi-media card (MMC) interface, but is not limited thereto. The card interface 7100 may exchange data between a host 60000 and the controller 1200 according to a protocol of the host 60000. According to an embodiment, the card interface 7100 may support a universal serial bus (USB) protocol, and an inter chip (IC)-USB protocol. Here, the card interface 7100 may refer to hardware capable of supporting a protocol that is used by the host 60000, software installed in the hardware, or a signal transmission method.

When the memory system 70000 is connected to a host interface 6200 of the host 60000 such as a PC, a tablet PC, a digital camera, a digital audio player, a mobile phone, a console video game hardware, or a digital set-top box, the interface 6200 may perform data communication with the memory device 1100 through the card interface 7100 and the controller 1200 under control of a microprocessor (μP) 6100.

What is claimed is:

1. A memory device comprising:
first and second material layers alternately stacked;
a vertical hole passing through the first and second material layers;
first insulating patterns protruding from a side surface of the first material layers exposed through the vertical hole;
a blocking layer formed along a surface of the second material layers exposed between the first insulating patterns, the blocking layer comprising a plurality of concave portions, each of which is between the first insulating patterns; and
charge trap patterns formed in the concave portions,
wherein portions of the blocking layer exposed between the charge trap patterns,
wherein a tunnel insulating layer, a channel layer, and a core pillar, are formed in an area that is substantially surrounded by the charge trap patterns.

2. The memory device of claim 1, wherein the first material layers are insulating layers, and the second material layers are conductive layers.

3. The memory device of claim 1, wherein the blocking layer extends over exposed surfaces of the first insulating patterns and the second material layers, in the vertical hole.

4. The memory device of claim 1, wherein the charge trap patterns are radially aligned with a second material layers.

5. The memory device of claim 1, wherein the charge trap patterns are spaced apart from each other.

6. The memory device of claim 1, wherein a width of the first material layers is substantially the same as a width of the second material layers.

7. The memory device of claim 1, wherein a width of the first material layers is less than a width of the second material layers.

8. The memory device of claim 7, wherein the vertical hole has a center axis and wherein the second material layers are located at second radial distance from the center axis and the first material layers are located at a first radial distance from the center axis, wherein the second radial distance is less than the first radial distance.

9. The memory device of claim 8, further comprising:
second insulating patterns formed in a portion where a width difference between the first and second materials layers occurs, between the second material layers.
